(19) United States
(12) Patent Application Publication
(10) Pub. No.: US 2004/0009629 A1
(43) Pub. Date: Jan. 15, 2004

(54) Electrode forming method in circuit device and chip package and multilayer board using the same

(75) Inventors: Moon Bong Ahn, Sungnam (KR); Kwang Cheol Cho, Suwon (KR)

Correspondence Address: LOWE HAUPTMAN GOPSTEIN GILMAN & BERNER, LLP, Suite 310, 1700 Diagonal Road, Alexandria, VA, 22314, US

(73) Assignee: Samsung Electro-Mechanics Co., Ltd.

(21) Appl. No.: 10/327,933

(22) Filed: Dec. 26, 2002

(30) Foreign Application Priority Data
Jul. 12, 2002 (KR) 2002-40712

(51) Int. Cl. H01L 21/44

(52) U.S. Cl. 438/108; 438/612; 438/613

(57) ABSTRACT

The present invention relates to an electrode forming method in circuit devices such as boards and chip devices, and a chip package and multilayer board using the same, in particular, in which protective bumps and an insulation layer are provided in terminal areas of a circuit device and then the protective bumps are removed to obtain via holes so that electrodes may be formed for electrical connection with other circuit elements. The invention provides an electrode forming method in a circuit device comprising the following steps of: forming protective bumps with a predetermined thickness on a plurality of electrodes in the circuit device; forming an insulating layer on the circuit device excluding areas for the protective bumps; polishing the insulating layer to expose the protective bumps to the outside; removing the protective bumps to expose the electrodes to the outside; forming a conductive layer on the insulating layer to be connected with the electrodes; and forming a pattern corresponding to the electrodes on the conductive layer and forming external electrodes on the pattern.

### BACKGROUND OF THE INVENTION

1. Field of the Invention

The present invention relates to an electrode forming method in circuit devices such as boards and chip devices, and a chip package and multilayer board using the same. In particular, protective bumps and an insulation layer are provided in terminal areas of a circuit device and then the protective bumps are removed to form via holes so that electrodes may be made for electrical connection with other circuit elements.

2. Description of the Related Art

Recently, packages for chip-type device are developing toward Chip Scale Packages (CSP) from those based upon lead frames and molding technology. Available examples of the CSP include a flip chip package and a wire bond-type package.

FIG. 1 shows a flip chip package. As shown in FIG. 1, a chip 101 is provided in the lower face with conductive bumps 111 connected with terminals of the chip. The conductive bumps 111 are mounted on upper electrodes of a board 103 which is electrically conductive in both faces. This connects each of the terminals in the chip 101 with each of the electrodes in the board 103. The board 103 is provided with via holes for electrically connecting the terminals of the chip 101, respectively, with solder balls 107, i.e. external electrodes provided in the lower face of the board 103. Further, a layer of protective insulating resin, e.g. epoxy resin, is filled around the chip 101 between the board 103 and the chip 101.

In the meantime, a wire bond-type package is shown in FIG. 2. As shown in FIG. 2, a chip 201 is mounted on the upper face of a conductive board 203 which is conductive in both faces. Wires 211 connect each of electrodes in the chip 201 with each of upper electrodes in the conductive board 203, respectively. Then a protective layer 205 made of resin, e.g. epoxy molding resin, is formed around the chip 201 and the wires 211. The board 203 is also provided with via holes 209 for electrically connecting each of the terminals in the chip 201 with each of external terminals 207 in the board 203.

Such chip scale packages each utilize a double-sided board and can be mounted on another circuit device, e.g. board, via the electrodes in the lower face of the double-sided board. Such double-sided boards 103 and 203 each function to electrically connect the terminals in the chip 101 or 201 with the terminals (not shown) in the main board on which the package is mounted, and protect the chip 101 or 201 as well.

The double-sided boards 103 and 203 each are conductively structured by perforating via holes in a substrate made of rigid material, e.g. phenol resin and ceramic, with a drill or laser, and then electrolessly plating upper and lower faces including the via holes. Then the substrate is electrolytically plated or etched to form a pattern in a plated layer, and coated with a layer of insulating material, e.g. solder resistant, on the entire portion thereof excluding the terminals.

At present, such a double-sided board utilizes a Ball Grid Array (BGA) board 303, as shown in FIG. 3, for the above high integrated and microscopic package. The BGA board 303 used in the package comprises a chip 301 attached to the upper face of the package and ball-shaped solders 307 (or solder balls) attached to the lower face opposed to the upper face in a two dimensional array for the purpose of surface mount. Although the balls 307 generally have a distance of about 1.5 mm among them, they can be arranged in the entire lower face of the package and connected to more external terminals than in the conventional packaging method. As a result, this creates an advantage that the chip package can be downsized.

In use of this type of board, it is required to downsize the via holes in a substrate as the chip and thus the package are downsized. However, it is technically difficult to downsize the via holes. Even though the via holes are formed in a smaller diameter, there is a problem that cost may be elevated. Further, there is a problem that it is difficult to use the high-integrated multilayer board owing to the difficulty of downsizing the via holes.

Accordingly it has been requested a technique for enabling substitution of the double-sided board, in which precise via holes are formed without using the double-side board for the purpose of connecting the external electrodes to the terminals of the chip, and also enabling a board to be multi-layered using precise via holes.

Furthermore, where the board is replaced with a flexible board, the flexible $$ board is provided with the via holes through chemical etching so that a face of the flexible board having the via holes shows more excellent conditions than the rigid board. However, there is a problem that a supplementary process is needed in order to prevent any thermal and physical impacts in a chip package fabrication stage.

Therefore there has been requested a noble structure of chip package and multilayer board in which smaller-sized via holes be formed in more precise positions and which are endurable to any thermal and physical impacts.

### SUMMARY OF THE INVENTION

The present invention has been made to solve the above problems and it is therefore an object of the present invention to provide precise and small-sized via holes by forming and removing protective bumps, and a downsized chip package and fabrication method thereof by using the via holes.

It is another object of the invention to substitute a layer of protective insulating resin for a board used in a chip package process to obtain a cheaper package as well as a more reliable package and multilayer board endurable to any thermal or physical impacts.

It is other object of the invention to form precise via holes from the above process so as to provide a high-integrated and small-sized multilayer board according to a simplified fabrication process, and a fabrication method thereof.

According to an aspect of the invention to obtain the above objects, it is provided an electrode forming method in a circuit device, the method comprising the following steps of: forming protective bumps with a predetermined thickness on a plurality of electrodes in the circuit device; forming an insulating layer on the circuit device excluding areas for the protective bumps; polishing the insulating layer to expose the protective bumps to the outside; removing the protective bumps to expose the electrodes to the outside; forming a conductive layer on the insulating layer to be connected with the electrodes; and forming a pattern corresponding to the electrodes on the conductive layer and forming external electrodes on the pattern.

According to another aspect of the invention to obtain the above objects, it is provided a chip package fabrication method comprising the following steps of: preparing a chip device having a plurality of electrodes; forming protective bumps with a predetermined thickness on the electrodes of the chip device; forming an insulating layer on a face of the chip device having the electrodes excluding areas the protective bumps; polishing the insulating layer to expose the protective bumps to the outside; removing the protective bumps to expose the electrodes to the outside; forming a conductive layer on the insulating layer to be connected with the electrodes; forming a pattern having areas where additional electrode can be formed corresponding to the electrodes on the conductive layer; and forming the additional electrodes and an electrode-protecting layer on the additional electrode areas in the pattern.

According to further another aspect of the invention to obtain the above objects, it is provided a chip package fabrication method comprising the following steps of: preparing a wafer with a plurality of chip devices, each of the chip devices having a plurality of electrodes in a first face; forming protective bumps at a predetermined thickness on the electrodes of the chip devices; forming an insulating layer on a face of the wafer excluding areas where the protective bumps are disposed; polishing the insulating layer to expose the protective bumps to the outside; removing the protective bumps to expose the electrodes; forming a conductive layer on the insulating layer to be connected with the electrodes; forming a pattern having areas where additional electrode can be formed corresponding to the electrodes on the conductive layer; forming external electrodes and an electrode-protecting layer on the additional electrode areas in the pattern; and dicing the wafer into the unit of chip packages.

According to other aspect of the invention to obtain the above objects, it is provided a multilayer board fabrication method comprising the following steps of: forming protective bumps with a predetermined thickness on a plurality of electrodes on a substrate; forming an insulating layer on a face of the board having the electrodes excluding the protective bumps; polishing the insulating layer to expose the protective bumps; removing the protective bumps to expose the electrodes to the outside; forming a conductive layer on the insulating layer to be connected with the electrodes; forming a pattern having areas where addition electrode can be formed corresponding to the electrodes on the conductive layer; and forming external electrodes and an electrode-protecting layer on the additional electrode areas in the pattern.

According to another aspect of the invention to obtain the above objects, it is provided a chip package comprising: a chip device with a plurality of electrodes; an insulating layer disposed on a face of the chip device having excluding areas where the electrodes are disposed; a conductive layer disposed on the insulating layer filling the electrode areas, the conductive layer being electrically separated for a predetermined gap to correspond to each of the electrode areas; external electrodes disposed on the conductive layer; and a resistant layer disposed around the external electrodes on the insulating layer.

According to still another aspect of the invention to obtain the above objects, it is provided a multilayer board comprising: a substrate having a plurality of electrodes in a face; an insulating layer disposed on the face of the substrate having the electrodes excluding areas where the electrodes are disposed; a conductive layer disposed on the insulating layer while filling the electrode areas, the conductive layer being electrically separated for a predetermined gap to correspond to the electrode areas; external electrodes disposed on the conductive layer; and a resistant layer disposed around the external electrode on the insulating layer.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view of a conventional flip chip package;

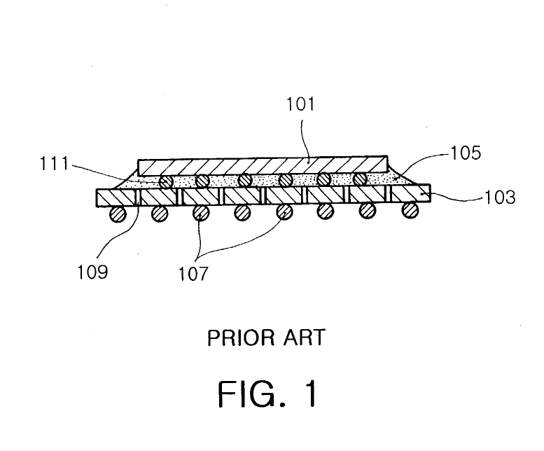

FIG. 2 is a sectional view of a conventional wire bond-type chip package;

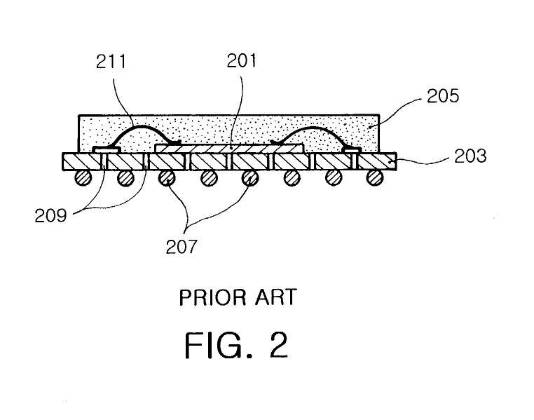

FIG. 3 is a sectional view of a conventional BGA board;

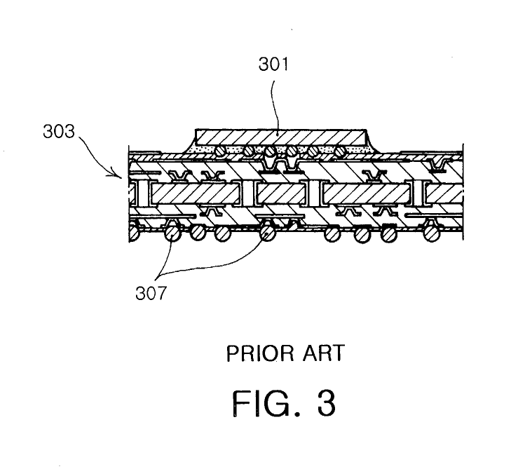

FIG. 4 is a sectional view of a chip package having electrodes according to an electrode forming method of the invention;

FIG. 5 is a step-wise sectional view of a chip package-fabrication method by using the electrode forming method of the invention;

FIG. 6 is a step-wise sectional view of a wafer level chip package-fabrication method by using the electrode forming method of the invention;

FIG. 7 is a sectional view of an embodiment of a chip package having a multilayer structure according to the invention;

FIG. 8 is a sectional view of an embodiment of a chip package having conductive layers in both faces according to the invention;

FIG. 9 is a sectional view of a chip package having an array structure of chips of the invention;

FIG. 10 is a sectional view of an embodiment of a chip package which is enhanced in lateral protection;

FIG. 11 is a sectional view of a multilayer board by using the electrode forming method of the invention; and

FIG. 12 is a step-wise sectional view of a fabrication method of the multilayer shown in FIG. 11.

### DETAILED DESCRIPTION OF THE PREFERRED EMBODIMENT

The following detailed description will present preferred embodiments of the invention in reference to the accompanying drawings.

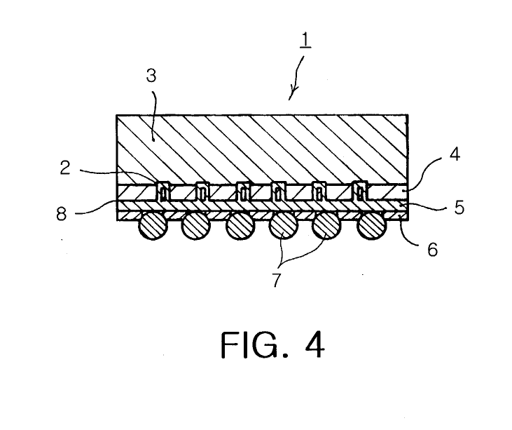

FIG. 4 is a sectional view of a chip package 1 obtained according to an electrode forming method of the invention. As shown in FIG. 4, a chip device 3 functions as an integrated circuit device which is provided with a plurality of electrodes in one face and optionally in the other face. An insulating layer 4 is formed in the chip device 3 over the face(s) where the electrodes are provided without enclosing the electrodes. The insulating layer 4 may be formed of insulating and protective resin, preferably epoxy molding resin. Hollow spaces in the insulating layer 4, i.e. electrode areas of the chip device 3 are electrolessly plated to have electric conductivity. Then a conductive layer 5 is formed via treatment such as electrolytic plating and/or etching. The conductive layer 5 has a pattern corresponding to the electrodes of the chip device 3. External electrodes 7 such as solder bumps are provided in portions of the conductive layer 5 which contact with the outside. A protective insulating resin layer 6 is formed in portions of the conductive layer 5 which require insulating-protection.

The chip package 1 of the invention provides the external electrodes corresponding to the electrodes in the chip device 1 without using a substrate as well as a noble chip package structure for realizing the same.

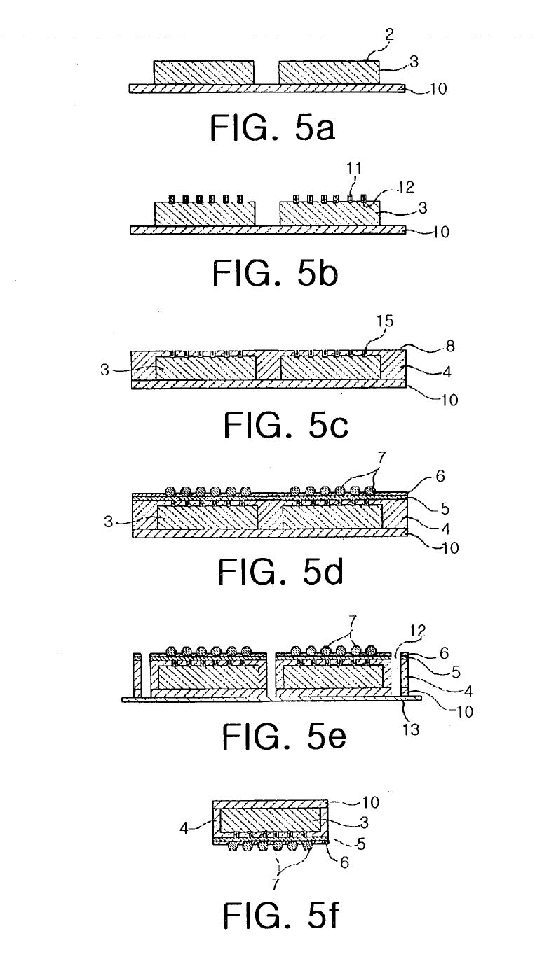

FIG. 5 is a step-wise sectional view of a chip package-fabrication method according to the first embodiment of the invention which adopts the electrode-forming method of the invention. In order to fabricate the chip package as shown in FIG. 4, the invention forms protective bumps which can be removed via stripping on chip electrodes and then removes the protective bumps so that via holes can be obtained in a smaller diameter.

For the purpose of this, the invention carries out the following steps: First, chip devices 3 each with a plurality of terminals are prepared. The chip devices 3 are one type of typical circuit devices and can function as substrates which will be described hereinafter. The plurality of terminals are provided in one or upper faces of the each chip device 3 and optionally in the lower face opposed to the upper face. This embodiment will be described on the basis of the chip devices 3 having the terminals only in the upper faces.

In the first step (a), the chip devices 3 each having the plurality of terminals in the upper face are mounted on a substrate 10, in which the lower faces opposed to the upper faces where the terminals are disposed are contacted with the underlying substrate 10. The substrate 10 is adapted to arrange a plurality of such chip devices 3 thereon while fixedly locating the chip devices and supporting chip package structures as well.

In the second step (b), protective bumps 11 are formed in terminal areas 2 of the chip devices 3 which are arranged on the substrate 10. The protective bumps 11 cover the terminal areas 2 of the chip devices 3 with a proper thickness. It is preferred in regard of the fabrication process if the protective bumps 11 have a thickness of 0.05 to 0.1 mm. The bumps 11 are made of photosensitive material, e.g. photoresist (PR) in this embodiment, since photoresist (PR) can be removed through stripping for forming via holes in the next step (c).

In the third step (c), an insulating layer 4 is formed over entire portions of the chip devices 3 excluding the protective bumps 11. The insulating layer 4 is made of protective insulating resin, preferably epoxy molding resin, and formed on the upper faces of the chip devices 3 where the terminals are provided and optionally on lateral faces thereof also. The insulating layer 4 provided on the lateral faces of the chip devices 3 fills spaces of the plurality of chip devices 3 arranged on the substrate 10.

The insulating layer 4 is formed higher than the protective bumps 11 and optionally may bury the protective bumps 11. Then the insulating layer 4 is polished since the protective bumps 11 are hardly removed if they are buried as above. This produces a polished surface in the upper face of the insulating layer 4 where the protective bumps 11 are formed, in which the polished surface is preferably parallel to the upper faces of the chip devices 3. Polishing is executed, e.g. according to a chemical mold polishing policy, so as to expose the protective bumps 11 to the outside.

The externally exposed protective bumps 11 are removed through stripping with etching solution. Then the protective bumps 11 are removed to expose the terminals 2 of the chip devices 3 to the outside. The protective bumps 11 can be removed with etching solution since they are made of photosensitive material such as photoresist. Those portions from which the protective bumps 11 are removed to form via holes 15.

After the protective bumps 11 are removed as above to expose the terminals of the chip devices, the via holes 15 and the chip electrodes 2 are electrolessly plated to have electric conductivity. A conductive layer 5 is formed on the insulating layer 4 while the via holes 15 are filled in the fourth step (d). The conductive layer 5 is connected to each of the terminals 2 of the chip devices, and preferably made of a metal such as copper. It is preferred that the conductive layer 5 preferably fills hollow spaces in the insulation layer 4 via the above plating for connection with the terminals 2. Alternatively, in order to have a uniform thickness, it is possible to form a thin plated layer via electrolytic plating and then layer at least one Cu film on the plated layer.

The conductive layer 5 is provided with a pattern so that additional terminals can be formed as opposed to the terminals 2 of the chip devices. External terminals 7 are formed in an area for the additional terminals, and a terminal-protecting layer 6 is formed around the external terminals 7. This embodiment adopts solder bumps as the external terminals 7.

After the above steps, a dicing tape 13 is attached to the substrate and then the substrate is diced so that the above structure can be divided into respective chip package units in the fifth step (e). Then the tape 13 is removed from articles in the sixth step (f).

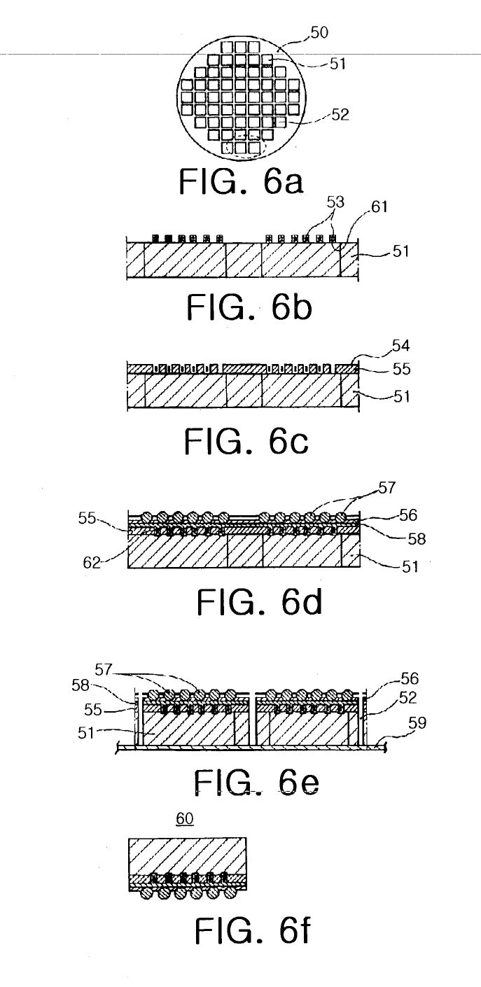

FIG. 6 is a step-wise sectional view of the second embodiment of a chip package fabrication method by using the electrode forming method of the invention. This embodiment relates to the fabrication method for the chip package in wafer level. Even though this embodiment has the same steps for the chip packages as in the first embodiment, chip devices are formed in a wafer and subjected to a chip package fabrication process before cut into respective chip units.

First, a wafer 50 is prepared which is provided with a plurality of chip devices each having a plurality of terminals in one face in step (a). Protective bumps 53 are formed in terminal areas 61 of the respective chip devices in the wafer as in the first embodiment in step (b) . The protective bumps 53 are preferably made of photosensitive material such as photoresist as above.

In step (c), an insulating layer 55 is formed on one face of the wafer 50 excluding those areas where the protective bumps 53 are formed. The one face of the wafer 50 means the face where the terminals of the chip devices are provided. The insulating layer 55 is formed higher than the protective bumps 53 and optionally may bury the protective bumps. The insulating layer 55 is polished in the upper portion so as to externally expose the protective bumps 53 as in the first embodiment. After polishing, stripping is carried out removing the protective bumps 53 with etching solution so that the terminals of the chip devices are exposed to the outside.

In step (d), upon completing the above processes, the terminals of the chip devices, hollow portions from which the protective bumps are removed and a polished surface are electrolessly plated to have electric conductivity thereby forming via holes 62. A conductive layer 58 is formed on the insulating layer 55 while filling the via holes 62. A pattern is provided on the conductive layer 58 to form areas where external electrodes will be formed so that the terminals of the chip devices can be connected with the outside. The external electrodes 57 are formed in the above areas and an electrode-protecting layer 56 is formed around the external electrodes.

After completing the above steps as in the first embodiment, a dicing tape is attached to the underside of the wafer 50 and then the wafer 50 is diced to divide into chip units in step (e). Wafer level chip packages 60 are obtained according to the above method.

In the chip package fabrication method by using the electrode forming method as in the first or second embodiment, it is possible to provide the insulating and conductive layers in plurality. That is to say, protective bumps are formed again with a predetermined thickness on the additional terminal areas in the pattern on the conductive layer, and the steps of forming and polishing an insulating layer, exposing the protective bumps, forming a conductive layer and forming a pattern are carried out so as to obtain a structure capable of substituting the multilayer board. These steps may be repeated at least once.

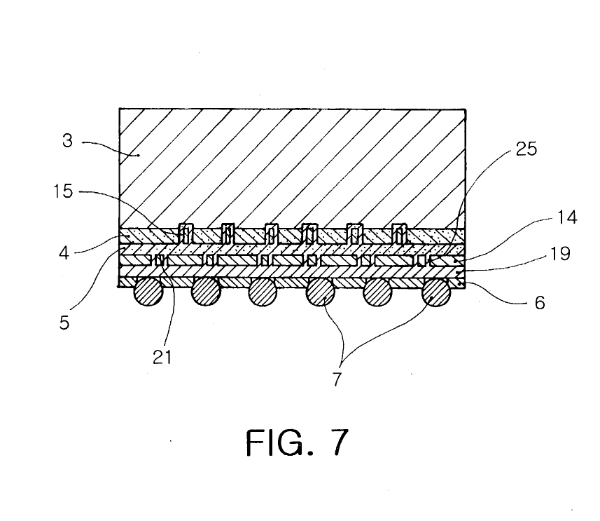

FIG. 7 shows the structure of such a chip package. In FIG. 7, an insulating layer 4 and via holes 15 are formed in one face of a chip device 3 which is subjected to having terminals. Although this structure is the same as in the above, the conductive layer 5 is patterned to form areas subjected to having additional terminals respectively corresponding to the first terminals. An insulating layer 14 is formed on the conductive layer 5 excluding the additional terminal areas, and via holes 25 are in the additional terminal areas. Further a conductive layer 19 is formed on the insulating layer 14 and fills the via holes 25 to electrically connect the terminals of the chip device with the outside, a pattern is formed on the conductive layer 19. A terminal-protecting layer 6 is formed around the external terminals. According to the method for fabricating the chip package which can substitute the multilayer board, a small-sized and high-integrated board can be realized so that the entire chip package can be advantageously downsized.

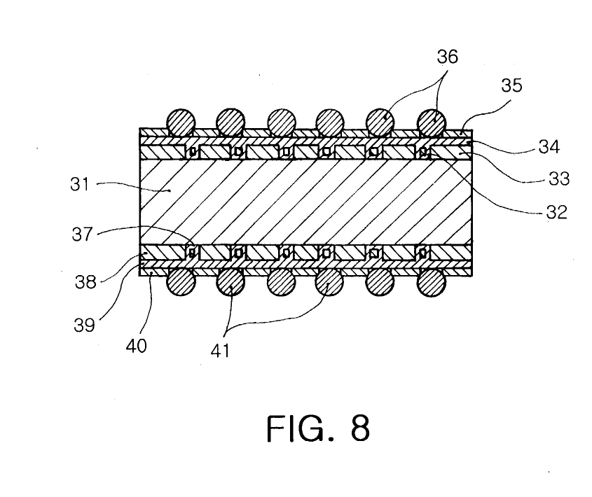

FIG. 8 is a sectional view of a chip package in which electrodes are formed in both faces by using a chip device which is stepped in both lateral faces according to the chip package fabrication method in any of the above embodiments. In FIG. 8, the chip device 31 is provided terminals in both faces where insulating layers 33 and 38 and via holes 32 and 37 are formed according to the method in FIG. 5 or 6. The via holes 32 and insulating layer 33 are covered with a conductive layer 34, and the via holes 37 and insulating layer 38 are covered with another conductive layer 39. The conductive layers 34 and 39 each are provided with a pattern corresponding to the terminals. The patterns each are provided with areas on which external terminals 36 and 41. Electrode-protecting layers 35 and 40 are formed, respectively, around the external electrodes 36 and 41. Like this, the chip device configured to have the terminals in the both faces can be manufactured into a package according to the method of the invention.

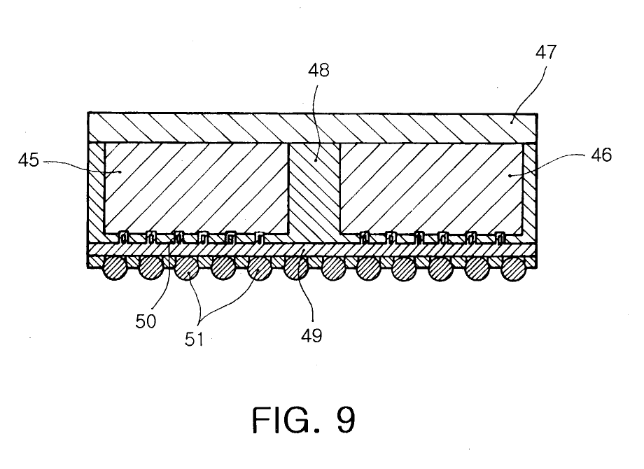

FIG. 9 is a sectional view of a chip package having an array structure of chips which is obtained from the unit chip package fabrication method according to any of the above embodiments. In FIG. 9, it is shown that the chip package has two chips 45 and 46. In the above type of chip package as seen in the first embodiment, each of the first and second chips 45 and 46 is attached to a substrate 47 by the upper face which is opposed to the lower face where terminals are provided. The chip package further comprises an insulating layer 48, via holes 50 and a conductive layer 49, which are provided between the terminals of the chips and external terminals 51, respectively. The chip package having the above chip array structure can so be fabricated to have a desired number of chips in the dicing step. Further, the structure shown in FIG. 9 can be also obtained by dicing the chip package according to the second embodiment so that a diced one would have a desired number of chips.

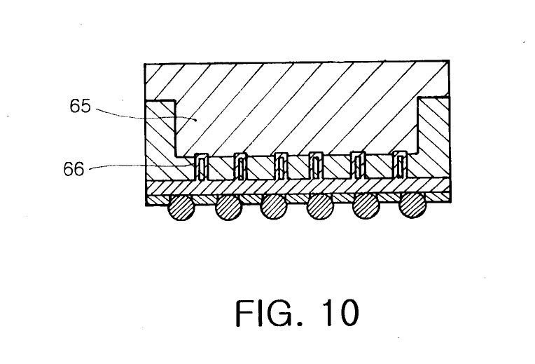

FIG. 10 shows the structure of a chip package similar to the above embodiments, which has lateral portions with steps and an insulating layer extended into the steps in the lateral faces. The structure of chip package is available, in particular, for a wafer level chip package as seen in the second embodiment. Lateral faces of the wafer level chip package are readily damaged since they are not insulated and function as lateral faces of the chip device. This structure of chip package is fabricated by forming grooves along cutting faces of chip device in a wafer having chip devices and introducing an insulating layer into the grooves in the pertinent step so that the lateral faces are made of the insulating layer in part. Therefore, the chip device 65 in FIG. 10 are partially cut in the lateral faces to form the steps. The insulating layer 66 is formed not only on stepped faces of the chip device 65 but also on portions of lateral faces thereof. Then portions of the lateral faces in the chip package can include the insulating layer so that the chip package is strengthened and not readily damaged.

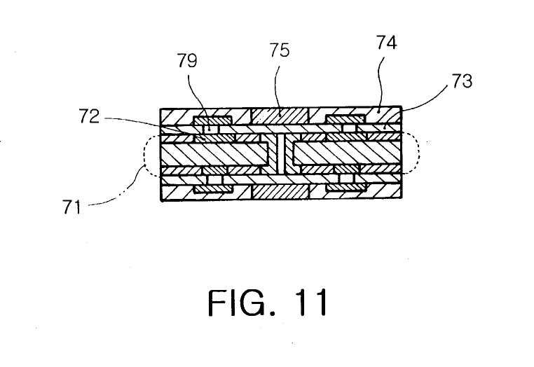

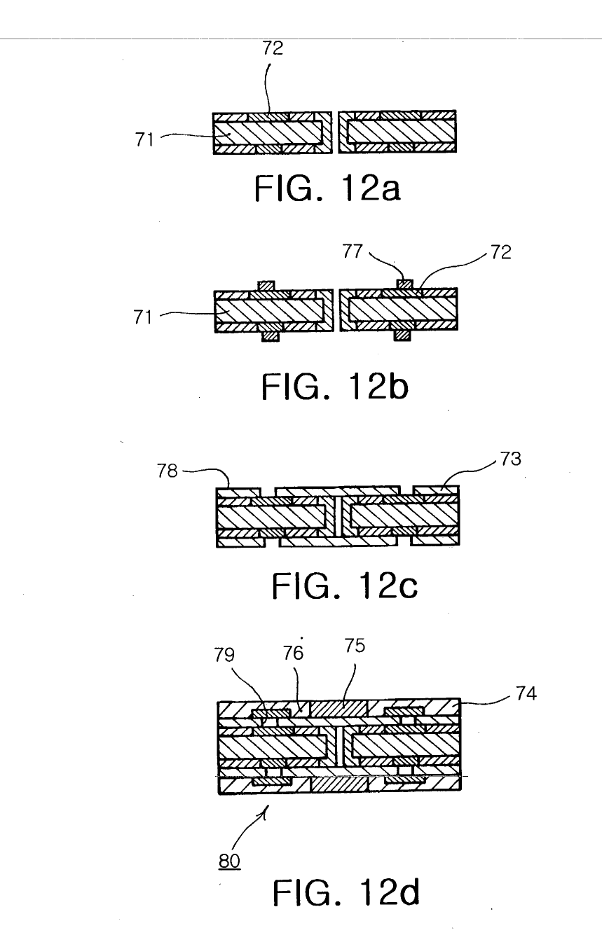

Hereinbefore it has been described about the chip package fabrication method adopting the electrode forming method of the invention for the chip device and the chip package using the same. In the meantime, the electrode forming method of the invention can be applied not only to chip devices but also to boards. FIG. 11 is a sectional view of a multilayer board fabricated by using the electrode forming method of the invention, and FIG. 12 is a step-wise sectional view of a fabrication method of the multilayer board shown in FIG. 11.

First, it is prepared a substrate 71 which is electrically conductive in both faces in step (a) . The substrate 71 may be provided with electrodes only in one face. Protective bumps 77 are formed over the electrodes 72 of the substrate 71 in step (b) . The protective bumps 77 are preferably made of photosensitive material, preferably photoresist, as in the first and second embodiments.

In step (c), an insulating layer 73 is formed on the face(s) of the substrate where the electrodes are provided excluding those areas where the protective bumps 77 are formed. The insulating layer 73 is formed higher than the protective bumps 77 and optionally may cover the protective bumps 77. Then the insulating layer 73 is polished in the upper face to externally expose the protective bumps 77 as in the first and second embodiments. After polishing, a stripping is carried out to remove the protective bumps 77 with etching solution to externally expose the electrodes of the board.

Subsequently in step (d), the electrodes of the board, those portions from which the protective bumps are removed and a polished surface 78 are electrolessly plated to have electric conductivity, by which via holes 79 are formed. A conductive layer 74 is formed on the insulating layer 73 while filling the via holes 79, and has a pattern to form areas where additional electrodes will be formed so as to connect the electrodes of the substrate with the outside. External electrodes 75 are formed in the additional electrode areas while electrode-protecting layers 76 are formed around the external electrodes. A multilayer board 80 is obtained after the steps as in the first and second embodiments.

When the substrate is flexible, it is preferred that the insulating layer utilizes molding resin which has no thermal defects. Further, the insulating layer is formed via injection molding, coating and so on.

The multilayer board obtained from this method is a four-layered board, but a multilayer board layered more than 4 times can be obtained as follows: Protective bumps are formed on the additional electrode areas in the pattern on the conductive layer 74. The steps of forming and polishing an insulating layer, exposing the protective bumps, forming a conductive layer and forming a pattern are carried out. Then these steps may be selectively repeated for at least one time to obtain the multilayer board which is layered more than 4 times.

According to the invention as set forth above, the protective insulating resin can substitute the substrate which is used in a conventional chip package process so as to advantageously reduce the cost of the package.

Also in fabrication of the chip package, the invention produces the via holes by forming the protective bumps in the substrate and then removing the bumps via stripping rather than physically forming the via holes so that the via holes can be obtain with a small diameter. This results in effects that the chip package can be downsized and the via holes can be correctly positioned.

In a conventional process of fabricating the chip package using a flexible substrate, the reliability of the board is problematic since it is flexible. However, the chip package fabrication process of the invention has an effect that the process is simplified since the solid protective resin substitutes the flexible substrate.

Further, even though the wire bond-type chip package disadvantageously creates chip package defects owing to deflection and cutting of a wire, the chip package of the invention excludes the use of wire so as to advantageously overcoming this problem.

According to the invention, a miniature chip package can be fabricated and the multilayer circuit can be designed so that the chip package can substitute the multilayer board.

In fabrication of the multilayer board also, the invention produces the via holes by forming the protective bumps in the substrate and then removing the bumps via stripping rather than physically forming the via holes so that the via holes can be obtain with a small diameter. This results in effects that the multilayer board can be downsized and the via holes can be correctly positioned.

Furthermore, the invention creates an effect that the high-integrated multilayer board can be obtained according to a simplified and down-priced fabrication process.

Although the invention has been shown and described with reference to the certain preferred embodiment thereof, it will be understood by those skilled in the art that various changes in form and details may be made therein without departing from the spirit and scope of the invention as defined by the appended claims.

What is claimed is:

1. An electrode forming method in a circuit device, the method comprising the following steps of:
forming protective bumps with a predetermined thickness on a plurality of electrodes in the circuit device;
forming an insulating layer on the circuit device excluding areas for the protective bumps;
polishing the insulating layer to expose the protective bumps to the outside;
removing the protective bumps to expose the electrodes to the outside;
forming a conductive layer on the insulating layer to be connected with the electrodes; and
forming a pattern corresponding to the electrodes on the conductive layer and forming external electrodes on the pattern.

2. An electrode forming method according to claim 1, wherein the circuit device is a chip device.

3. An electrode forming method according to claim 1, wherein the circuit device is a board.

4. An electrode forming method according to claim 1, wherein the protective bumps are made of photosensitive material.

5. An electrode forming method according to claim 4, wherein the protective bumps are removed via stripping.

6. An electrode forming method according to claim 4, wherein the photosensitive material is photoresist.

7. An electrode forming method according to claim 1, wherein the insulating layer is formed higher than the protective bumps.

8. An electrode forming method according to claim 1, wherein the conductive layer is formed via plating.

9. An electrode forming method according to claim 1, wherein the conductive layer comprises a metal layer containing Cu.

10. An electrode forming method according to claim 1, wherein the insulating layer is polished horizontal to a face of the circuit device.

11. A chip package fabrication method comprising the following steps of:
(a) preparing a chip device having a plurality of electrodes;
(b) forming protective bumps with a predetermined thickness on the electrodes of the chip device;
(c) forming an insulating layer on a face of the chip device having the electrodes excluding areas the protective bumps;
(d) polishing the insulating layer to expose the protective bumps to the outside;
(e) removing the protective bumps to expose the electrodes to the outside;
(f) forming a conductive layer on the insulating layer to be connected with the electrodes;
(g) forming a pattern having areas where additional electrode can be formed corresponding to the electrodes on the conductive layer; and
(h) forming the additional electrodes and an electrode-protecting layer on the additional electrode areas in the pattern.

12. A chip package fabrication method according to claim 11, wherein the chip device is an integrated circuit device.

13. A chip package fabrication method according to claim 12, wherein the step of preparing the chip device comprises: preparing a substrate to which the chip device is attached by a second face without the electrodes, wherein the chip devices comprises at least two chip devices.

14. A chip package fabrication method according to claim 11, wherein the chip device is an integrated circuit device which has the electrodes in a first face and a second face opposed thereto.

15. A chip package fabrication method according to claim 11, wherein the protective bumps are made of photosensitive material.

16. A chip package fabrication method according to claim 15, wherein the protective bumps are removed via stripping.

17. A chip package fabrication method according to claim 15, wherein the photosensitive material is photoresist.

18. A chip package fabrication method according to claim 11, wherein the insulating layer is formed higher than the protective bumps.

19. A chip package fabrication method according to claim 11, wherein the conductive layer is formed via plating.

20. A chip package fabrication method according to claim 11, wherein the conductive layer comprises a metal layer containing Cu.

21. A chip package fabrication method according to claim 11, wherein the insulating layer is polished horizontal to the face of the chip device having the electrodes.

22. A chip package fabrication method according to claim 11, further comprising the step of:
(i) forming additional protective bumps with a predetermined thickness on the additional electrode areas in the pattern;
(j) performing the steps of (c) forming an insulating layer, (d) polishing the insulating layer, (e) exposing the electrodes, (f) forming a conductive layer and (g) forming a pattern; and
(k) optionally repeating the (i) and (j) steps at least once.

23. A chip package fabrication method comprising the following steps of:
(a) preparing a wafer with a plurality of chip devices, each of the chip devices having a plurality of electrodes in a first face;
(b) forming protective bumps at a predetermined thickness on the electrodes of the chip devices;
(c) forming an insulating layer on a face of the wafer excluding areas where the protective bumps are disposed;
(d) polishing the insulating layer to expose the protective bumps to the outside;
(e) removing the protective bumps to expose the electrodes;
(f) forming a conductive layer on the insulating layer to be connected with the electrodes;
(g) forming a pattern having areas where additional electrode can be formed corresponding to the electrodes on the conductive layer;
(h) forming external electrodes and an electrode-protecting layer on the additional electrode areas in the pattern; and
(i) dicing the wafer into the unit of chip packages.

24. A chip package fabrication method according to claim 23, wherein the chip devices are integrated circuit devices each having the electrodes in a face.

25. A chip package fabrication method according to claim 23, wherein the protective bumps are made of photosensitive material.

26. A chip package fabrication method according to claim 25, wherein the protective bumps are removed via stripping.

27. A chip package fabrication method according to claim 25, wherein the photosensitive material is photoresist.

28. A chip package fabrication method according to claim 23, wherein the insulating layer is formed higher than the protective bumps.

29. A chip package fabrication method according to claim 23, wherein the conductive layer is formed via plating.

30. A chip package fabrication method according to claim 23, wherein the conductive layer comprises a metal layer containing Cu.

31. A chip package fabrication method according to claim 23, wherein the insulating layer is polished horizontal to the faces of the chip devices having the electrodes.

32. A chip package fabrication method according to claim 23, further comprising the step of:
(j) forming additional protective bumps with a predetermined thickness on the additional electrode areas in the pattern;
(k) repeating the steps of (c) forming an insulating layer, (d) polishing the insulating layer, (e) exposing the electrodes, (f) forming a conductive layer and (g) forming a pattern; and
(l) optionally repeating the (j) and (k) steps at least once.

33. A multilayer board fabrication method comprising the following steps of:
(a) forming protective bumps with a predetermined thickness on a plurality of electrodes on a substrate;
(b) forming an insulating layer on a face of the board having the electrodes excluding the protective bumps;
(c) polishing the insulating layer to expose the protective bumps;
(d) removing the protective bumps to expose the electrodes to the outside;
(e) forming a conductive layer on the insulating layer to be connected with the electrodes;
(f) forming a pattern having areas where addition electrode can be formed corresponding to the electrodes on the conductive layer; and
(g) forming external electrodes and an electrode-protecting layer on the additional electrode areas in the pattern.

34. A multilayer board fabrication method according to claim 33, wherein the electrodes are formed in a first face of the substrate.

35. A multilayer board fabrication method according to claim 33, wherein the substrate is electrically conductive in both faces, and the electrodes are formed in the first face and the second face opposed thereto.

36. A multilayer board fabrication method according to claim 33, further comprising the step of:
(h) forming protective bumps with a predetermined thickness on the additional electrode areas in the pattern;
(i) repeating the steps of (b) forming an insulating layer, (c) polishing the insulating layer, (d) removing the protective bump, (e) forming a conductive layer and (f) forming a pattern; and
(j) optionally repeating the (j) and (k) steps at least once.

37. A multilayer board fabrication method according to claim 33, wherein the protective bumps are made of photosensitive material.

38. A multilayer board fabrication method according to claim 37, wherein the protective bumps are removed via stripping.

39. A multilayer board fabrication method according to claim 37, wherein the photosensitive material is photoresist.

40. A multilayer board fabrication method according to claim 33, wherein the insulating layer is formed higher than the protective bumps.

41. A multilayer board fabrication method according to claim 33, wherein the conductive layer is formed via plating.

42. A multilayer board fabrication method according to claim 33, wherein the conductive layer comprises a metal layer containing Cu.

43. A multilayer board fabrication method according to claim 33, wherein the insulating layer is polished horizontal to the face of the substrate having the electrodes.

44. A chip package comprising:
a chip device with a plurality of electrodes;
an insulating layer disposed on a face of the chip device having excluding areas where the electrodes are disposed;
a conductive layer disposed on the insulating layer filling the electrode areas, the conductive layer being electrically separated for a predetermined gap to correspond to each of the electrode areas;
external electrodes disposed on the conductive layer; and
a resistant layer disposed around the external electrodes on the insulating layer.

45. A chip package according to claim 44, wherein the chip device is an integrated circuit device which has the electrodes in a first face.

46. A chip package according to claim 44, wherein the chip device comprises at least two chip devices.

47. A chip package according to claim 46, further comprising a substrate to which the chip devices each are attached by a second face without the electrodes.

48. A chip package according to claim 44, wherein the chip device is an integrated circuit device which has the electrodes in the first face and a second face corresponding thereto.

49. A chip package according to claim 44, wherein the insulating layer is further disposed on a predetermined portion of a lateral face of the chip device.

50. A chip package according to claim 44, wherein the insulating layer is horizontal to the face of the chip device having the electrodes.

51. A chip package according to claim 44, wherein the conductive layer is formed via plating.

52. A chip package according to claim 44, wherein the conductive layer comprises a metal layer containing Cu.

53. A chip package according to claim 44, further comprising:
at least a pair of second insulating layers disposed on the insulating layer while filling the electrode areas and the second insulating layer on the conductive layer excluding the electrode areas, the pair of second insulating layers being electrically separated for a predetermined gap to correspond to the electrode areas,
wherein the external electrodes are disposed on the conductive layer in the outermost position, and the resistant layer is disposed over the insulating layer in the outermost position.

54. A multilayer board comprising:
a substrate having a plurality of electrodes in a face;
an insulating layer disposed on the face of the substrate having the electrodes excluding areas where the electrodes are disposed;
a conductive layer disposed on the insulating layer while filling the electrode areas, the conductive layer being electrically separated for a predetermined gap to correspond to the electrode areas;
external electrodes disposed on the conductive layer; and
a resistant layer disposed around the external electrode on the insulating layer.

55. A multilayer board according to claim 54, wherein the electrodes are disposed in a first face of the substrate.

56. A multilayer board according to claim 54, wherein the substrate is electrically conductive in both faces, and wherein the electrodes are disposed on a face and a second face opposed to the first face.

57. A multilayer board according to claim 54, wherein the conductive layer is formed via plating.

58. A multilayer board according to claim 54, wherein the conductive layer comprises a metal layer containing Cu.

59. A multilayer board according to claim 54, wherein the insulating layer is polished horizontal to the face of the substrate having the electrodes.

60. A multilayer board according to claim 54, further comprises:
at least a pair of second insulating layers disposed on the insulating layer while filling the electrode areas and the second insulating layer on the conductive layer excluding the electrode areas, the pair of second insulating layers being electrically separated for a predetermined gap to correspond to the electrode areas,
wherein the external electrodes are disposed on the conductive layer in the outermost position, and the resistant layer is disposed on the insulating layer in the outermost position.
